(19) United States
(12) Patent Application Publication
(10) Pub. No.: US 2024/0421001 A1
(43) Pub. Date: Dec. 19, 2024

(54) Process for the Pulsed Laser Ejection of Multiple Epitaxial Structures from one Thin Film Growth

(71) Applicant: The Board of Trustees of the Leland Stanford Junior University, Stanford, CA (US)

(72) Inventors: Benjamin Reeves, Bellville, TX (US); Bruce M. Clemens, Stanford, CA (US)

(21) Appl. No.: 18/706,228

(22) PCT Filed: Nov. 8, 2022
(86) PCT No.: PCT/US2022/049296

§ 371 Date: Apr. 30, 2024

Related U.S. Application Data
(60) Provisional application No. 63/277,079, filed on Nov. 8, 2021.

(51) Int. Cl. H01L 21/78; H01L 21/683

(52) U.S. Cl. CPC H01L 21/7813; H01L 21/6835; H01L 2221/6835

(57) ABSTRACT

We provide a technique that can rapidly and sequentially separate multiple sets of thin films from a wafer, effectively multiplying the number of epitaxial structures that may be recovered per wafer reuse, and therefore increasing throughput and reducing costs. A multilayer structure is formed of alternating epitaxial structures and sacrificial structures, with the entire stack disposed on a substrate structure. Then laser liftoff is performed one sacrificial structure at a time, to individually release the epitaxial structures from the substrate (and from each other).

### FIELD OF THE INVENTION

This invention relates to laser liftoff of epitaxial structures.

### BACKGROUND

Single crystal semiconductor wafers provide excellent properties to make, for example, electronic and optoelectronic devices. However, wafers are typically hundreds to hundreds of thousands times thicker than active device layers, and can be expensive and difficult to grow. It is therefore desirable to use wafers to create high quality, single-crystalline, thin film device layers and/or device structures, but without sacrificing the wafer. This can be done, for example, by growing high-quality layers on the wafers, removing the layers from the wafer, and then repeating the cycle as many times as possible. Typical thin film removal and wafer recovery techniques remove a single layer or a single multilayer structure from the wafer before the wafer is reused.

### SUMMARY

This work provides a technique that can rapidly and sequentially separate multiple sets of thin films from a wafer, effectively multiplying the number of epitaxial structures that may be recovered per wafer reuse, and therefore increasing throughput and reducing costs. A multilayer structure is formed of alternating epitaxial structures and sacrificial structures, with the entire stack disposed on a substrate structure. Then laser liftoff is performed one sacrificial structure at a time, to individually release the epitaxial structures from the substrate (and from each other).

Applications of this technique can include single-crystal III-V electronic or optoelectronic thin film devices such as high-efficiency single- and multi-junction III-V solar cells, LEDs, transistors, and detectors (including e.g. ejected device arrays), or semiconductor-on-insulator layers for e.g. nanophotonics or waveguiding structures.

Numerous significant advantages are provided.
1) This approach utilizes the unique benefits of laser liftoff relative to other wafer recovery techniques, e.g., the process can take second or minutes instead of hours and does not require long substrate acid exposure.
2) This work allows for multiple devices from each substrate use instead of one. It is possible that the devices grown closest to the substrate could perform worse than the devices grown last because of e.g. dopant diffusion during the additional device growths. Ignoring such uncertainty, this process would have the same effect as multiplying the number of possible wafer recovery cycles by x, where x is the number of devices grown per growth process. In other words, if a wafer can be reused 10 times with the laser liftoff process, growing 5 devices per growth would be equivalent to reusing the wafer 50 times, therefore lowering the average substrate cost.
3) Compared to laser liftoff of a single device, this process reduces the average energy consumed per device produced by utilizing only a single substrate heating and cooling cycle per set of x devices, thus reducing the time for energy payback. Material consumption is also lower, because e.g. steps such as buffer growth or cleaning during epitaxial deposition might be performed one or fewer times on average per set of x devices made.
4) Poor surface quality can interfere with the laser pulse and result in partial or failed film ejection. Sending the laser pulse through the device instead of the substrate removes the need to protect the optical quality of the substrate backside (i.e. lower surface) during thin film growths.
5) The volume required for light removal and ejection can be very small, and the process requires the fundamental minimum amount of contact necessary to remove or bond and remove a layer.
6) Layers never exposed during the production of many sets of devices and heating/cooling cycles can be exposed at any time by choices of selective etches post light removal of devices. So the original substrate surfaces can be preserved independently of the device removal and growth processes.
7) This work can provide for less stringent bonding conditions than the bonding of two wafers. A thin film bonding process after layer removal, for example, may produce far lower thermal stress and concomitant issues for the same temperature change, owing to the thin bonding process instead of bonding two different thick materials.
8) This work removes the condition that the layers be flexed during film removal, and provides for independent control of mechanical forces and device removal, therefore improving e.g. post-removal device production and bonding by preserving large smooth surfaces with e.g. warping and bowing properties as good or better than the original device wafer.
9) This approach is compatible with many material systems. Other material systems can be for example InP devices with InGaAs absorbers, AlGaSb with GaSb, or any material system that has high quality crystalline multilayers with highly (or even slightly) different optical absorption properties.
10) This approach permits a huge variety of laser pulses. The device layers can be very thin, which permits laser pulses that might normally absorb while travelling through a thick substrate. For example femtosecond laser pulses, or above bandgap light, might not be a permissible laser pulse for device removal when sending the light through the wafer, but may become permissible when sending light through a thin device layer.
11) This approach can reduce etch times and acid exposure of final interfaces to the minimum possible. This can reduce the amount of chemical byproducts left on interfaces to the lowest level possible. This can also result in smooth interfaces for even pairs of etch stop/device or etch stop/etch stop or etch stop/wafer layers that do not have highly selective etch options.

### BRIEF DESCRIPTION OF THE DRAWINGS

FIGS. 1A-H show a first embodiment of the invention.

FIGS. 2A-B shows use of a carrier to hold an ablatively released structure in place.

FIGS. 3A-B show an alternative where ablative release is performed by illuminating the structure from the bottom.

FIGS. 4A-B show an example of a multi-layer semiconductor substrate structure.

FIGS. 5A-C show a first option for a clean-up process after an ablative release.

FIGS. 6A-C show a second option for a clean-up process after an ablative release.

FIG. 7 shows solar cell device results from a single-ejection experiment.

### DETAILED DESCRIPTION

### A) Summary of Single-Layer Release

We begin by describing the removal of a single layer by ablative release as considered in U.S. Pat. No. 9,698,053, which is incorporated herein by reference in its entirety. This process may be used to produce many types of devices, so we call all of the thin film layers that form a part of the removed layers an “epitaxial structure.” Although the process can work with many material systems and types of wafers, we describe an example process using III-As semiconductor alloys (e.g. GaAs, AlGaAs) and a GaAs wafer. The first step of the process occurs during III-V device thin film synthesis (e.g. metal-organic chemical vapor deposition). We grow a set of layers called a “sacrificial structure” on the GaAs substrate. This sacrificial structure, can be e.g., an “absorber layer” sandwiched between two “etch stop layers.” Here, we choose a GaAs absorber layer sandwiched between two AlAs etch stop layers, i.e. AlAs|GaAs|AlAs. The etch stop layers and absorber layer can all be chosen to be lattice matched or nearly-lattice matched to the GaAs substrate material (here, because of the very similar structural properties of AlAs and GaAs), so the set of device layers grown on top of the sacrificial structure can have crystalline quality that matches or exceeds the growth substrate quality. This helps ensure that the final device has the highest optoelectronic quality. We continue the growth by growing the epitaxial structure, i.e. our final grown structure from the bottom up is a GaAs substrate, a sacrificial structure, and an epitaxial structure. Here, we choose a simple Al_{0.5}Ga_{0.5}As layer to be the “device.” In order of growth, our final example structure is therefore

(100) GaAs|AlAs|GaAs|AlAs|Al_{0.5}Ga_{0.5}As, where we choose here a (100) GaAs substrate. The GaAs absorber layer has a small optical band gap relative to the device-side AlAs etch stop and the Al_{0.5}Ga_{0.5}As device. Because of this, by choosing the properties of one or more light sources, e.g. continuous or pulsed lasers, we may transmit a laser pulse through the device side of the structure that absorbs strongly in the GaAs absorber layer, but does not absorb strongly in the Al_{0.5}Ga_{0.5}As device or device-side AlAs etch stop. This can cause the thin film device layers to be driven away from the substrate, thus separating the device layers from the substrate. It is convenient to refer to this process as “ablative release”, without being bound by any theory as to which specific physical processes dominate in the laser release of such semiconductor structures. Thus we define “ablative release” as any process or processes that lead to separation of semiconductor layers when an intermediate layer absorbs pulsed laser radiation.

The etch stop layer material can be chosen such that it has a very high etch rate relative to the layer adjacent to the etch stop under certain conditions. For example, AlAs on a GaAs substrate may be dissolved away in hydrofluoric acid very quickly, but the hydrofluoric acid effectively does not etch the GaAs surface once the AlAs is gone. After the light ejects the device layer, the two new surfaces (one on the substrate, and one on the device layers) include “melt debris,” i.e. absorber layer material left over from the melting and ejection during light liftoff, and an etch stop. The melt debris may have different etch selectivity than the etch stops, so an acid could etch away the melt debris on each surface, e.g. in a moments long dip into the acid. Then, another acid can etch away the etch stops (one for the substrate, and one for the released device layers). Similarly, the absorber and etch stops could both be dissolved in one acid that stops at a surrounding interface, such as the substrate. In any case, we are left with two new pristine surfaces: the device surface can continue on for additional processing, and the substrate may be returned to the growth chamber for reuse.

This example relates to laser liftoff of a single epitaxial structure followed by re-use of the substrate. Embodiments of the present invention relate to laser liftoff of two or more epitaxial structures, individually, followed by re-use of the substrate.

### B) Multi-Layer Release

For the special case of two periods, for example, beginning from the substrate, we would have a sacrificial structure, an epitaxial structure, another sacrificial structure, and finally another epitaxial structure. Now, a laser pulse sent through the top epitaxial structure can absorb into the top absorber layer, ejecting the upper epitaxial structure. Etching proceeds as previously described, except now, etching on the substrate side reveals the top of a new epitaxial structure. Another laser pulse can now be sent through this epitaxial structure for a second ejection. Etching proceeds yet again to reveal another new device surface and the original substrate surface. By sending the laser pulse through the device layers, we can therefore eject one or more device layers at a time from a stack of devices. We could for example grow five periods during one growth, and then eject five devices, all from a single wafer and growth cycle. Each ejected epitaxial structure can be a different product and there are many important products. For example, one epitaxial structure might be a simple GaAs thin film bonded to Si for someone to grow their own devices, then the next epitaxial structure may be a solar cell bonded to glass, etc.

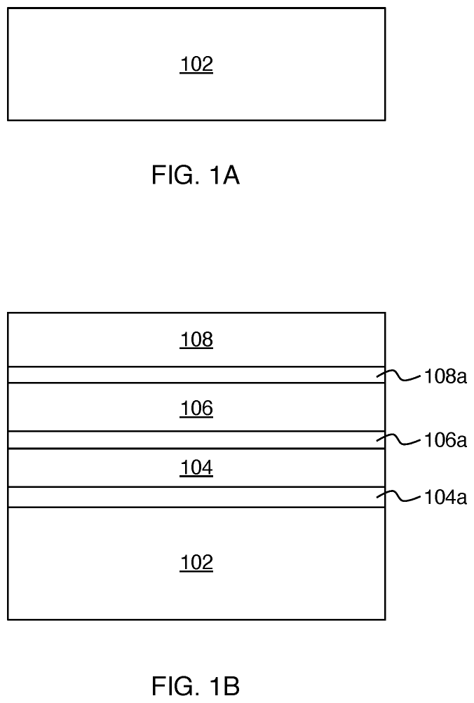

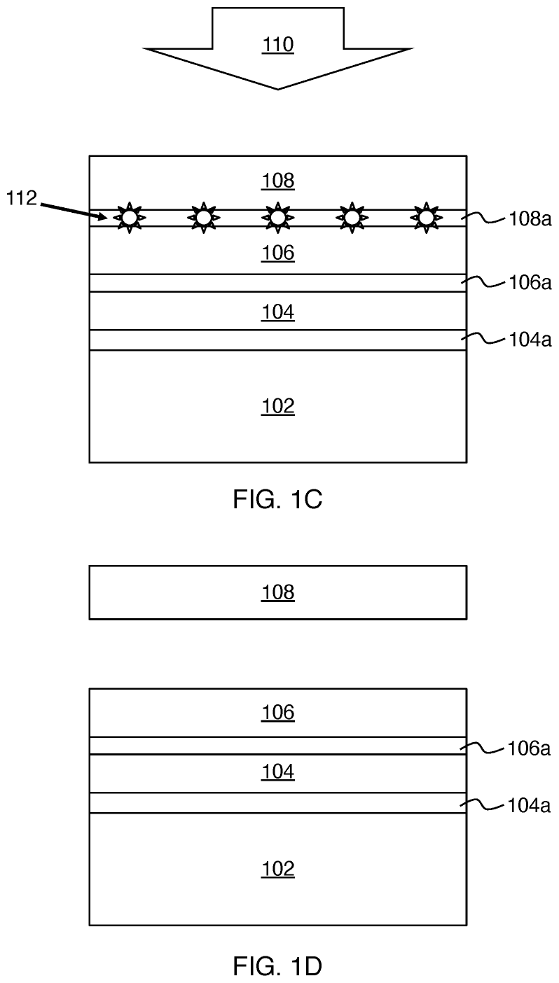

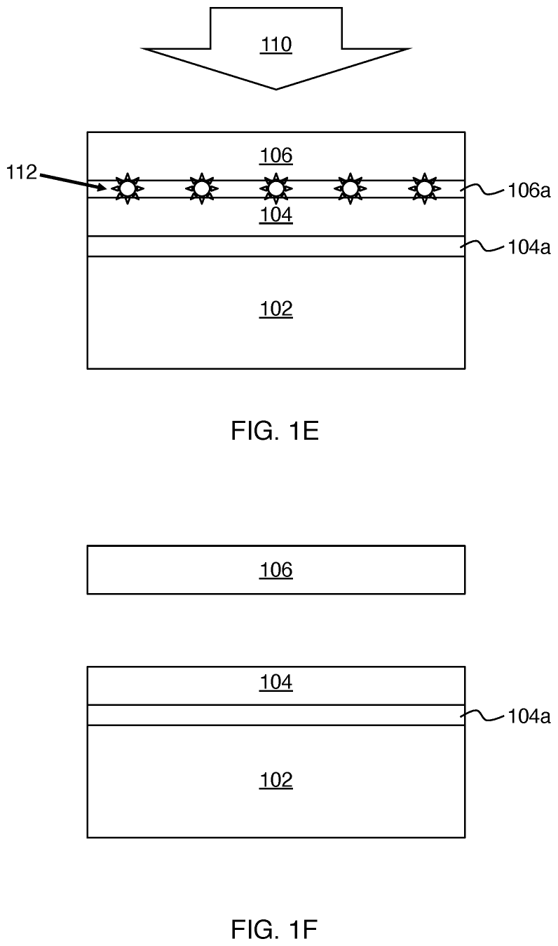

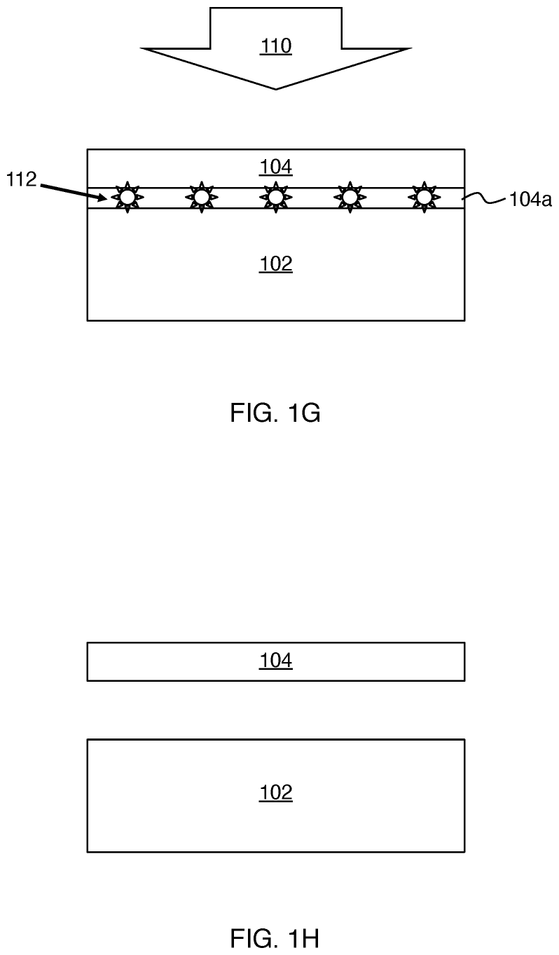

FIGS. 1A-H show a first embodiment of the invention. In this example, the first step is epitaxially depositing a multilayer stack (104a, 104, 106a, 106, 108a, 108) on a semiconductor substrate structure 102. The multilayer stack includes an alternating sequence of two or more distinct epitaxial structures (104, 106, 108) and two or more sacrificial structures (104a, 106a, 108a). A bottom part of the multilayer stack that is in contact with the semiconductor substrate structure 102 is one of the sacrificial structures (i.e., 104a). This step results in the structure of FIG. 1B starting from the substrate of FIG. 1A.

FIGS. 1C-D schematically shows the result of illuminating the multilayer stack with one or more pulses of laser radiation 110 such that absorption of the laser radiation in a selected one of the sacrificial structures provides ablative release from each other of structures sandwiching the selected one of the sacrificial structures (this release is schematically shown as 112). Here sacrificial layer 108a is ablated to release layer 108.

This ablative release step is repeated one or more times, with each repetition having a different one of the sacrificial structures selected as the one being ablated. Thus FIGS. 1E-F show ablation of sacrificial region 106a to release layer 106, and FIGS. 1G-H show ablation of sacrificial region 104a to release layer 104. The overall result is a sequence of two or more ablative releases.

Practice of the invention does not depend critically on lattice matching within the multilayer structure. A first option is lattice-matching both the epitaxial structures and the sacrificial structures to the semiconductor substrate structure. A second option is where the epitaxial structures are lattice-matched to the semiconductor substrate structure and the sacrificial structures are strained layers that lattice match to the semiconductor substrate structure via strain.

In some embodiments, a mechanical force within the multilayer stack can contribute to one or more of the ablative releases. Such a mechanical force can be generated by a coefficient of thermal expansion mismatch in the multilayer stack.

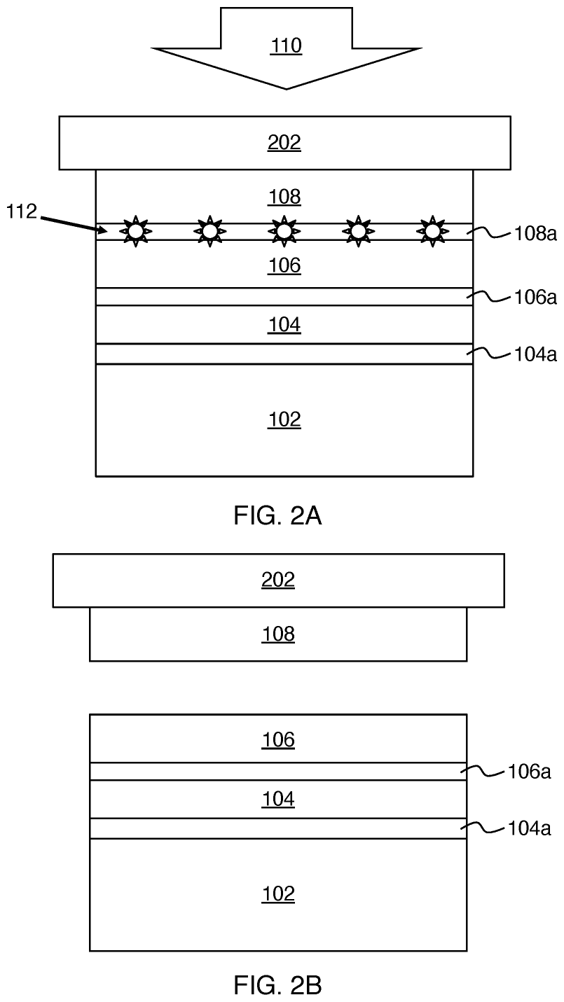

FIGS. 2A-B shows use of a carrier to hold an ablatively released structure in place. In this example, a carrier 202 is bonded to epitaxial structure 108 (FIG. 2A). Next, sacrificial region 108a is ablated, with the result that the released epitaxial structure 108 ends up disposed on carrier 202, as shown on FIG. 2B. Such carriers can be used for none, some or all of the released epitaxial structures.

Prior to ejection, we could deposit a transparent (to the laser pulse) carrier layer or layers on the top device surface, through which the laser pulse could pass, or surround the structures by a vacuum, liquid, plasma, or solid. The carrier could for example provide mechanical support to the ejecting film, be part of a devices' final anti-reflection coating layer, form a temporary bonding layer to transfer the film to a new substrate, form a longer term or permanent bond to a device carrier material, have a range of properties from vacuum (i.e. no layer) to rigid, flexible, viscous, volatile, compressible or incompressible, thermally conductive or insulating. This carrier could be patterned to allow for post-ejection processing, e.g. trenches could be created using a shadow-mask during the layer's deposition. These patterns could be used to, for example, shape the electroplating of gold contacts on the device's top surface after light ejection. As long as the carrier doesn't interfere with the film ejection it can be tailored to benefit subsequent device processing.

In the example of FIGS. 2A-B, laser radiation 110 is incident on the top part of the multilayer stack. That means it passes through carrier 202, so carrier 202 is transparent to laser radiation 110. For a “transparent” carrier, as long as enough light gets to the absorber and damage to the carrier is minimum/acceptable, some amount of absorption can be acceptable. The same reasoning applies to any epitaxial structure (or substrate) between the absorbing sacrificial structure and the light source.

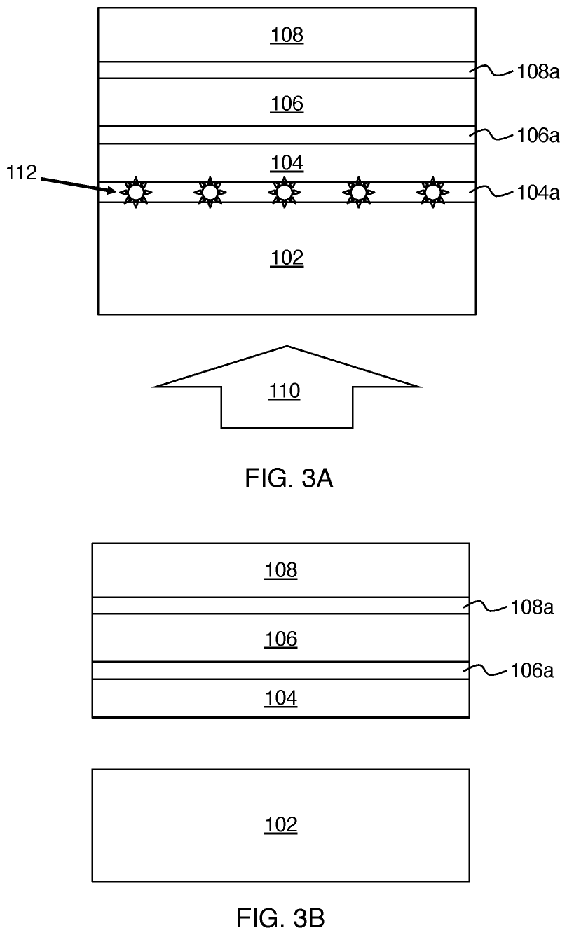

The example of FIGS. 1A-H shows the sequence of ablative releases being from top to bottom of the multilayer stack, where the laser radiation is incident on the top part of the multilayer stack. FIGS. 3A-B show an alternative where ablative release is performed by illuminating the structure from the bottom. In this embodiment, substrate 102 is sufficiently transparent to laser radiation 110 as described above. Repeatedly ablating from the bottom generates a sequence of ablative releases from bottom to top of the multilayer stack.

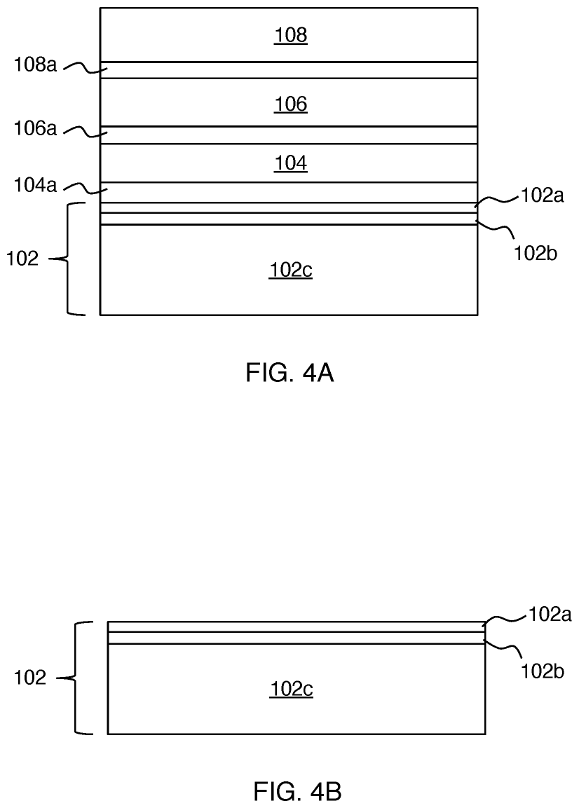

FIGS. 4A-B show an example of a multi-layer semiconductor substrate structure. Here semiconductor substrate structure 102 includes layers 102a and 102b on a true substrate 102c. As indicated in the discussion below, such structures can be helpful for reusing the substrate. Thus, after performing a multilayer ablative liftoff as described above, the semiconductor substrate structure can be prepared for re-use. After depositing another multilayer stack on the substrate structure, individual layers within the multilayer stack can be ablatively released as described above. In principle, the substrate can be reused indefinitely. In example 4 below, 102c is a GaAs substrate, 102b is a GaInP layer and 102a is an AlAs layer. If GaInP layer 102b become excessively fouled after repeatedly reusing the substrate structure, it can be etched away to reveal a pristine GaAs surface on which new GaInP and AlAs layers can be deposited to facilitate substrate re-use.

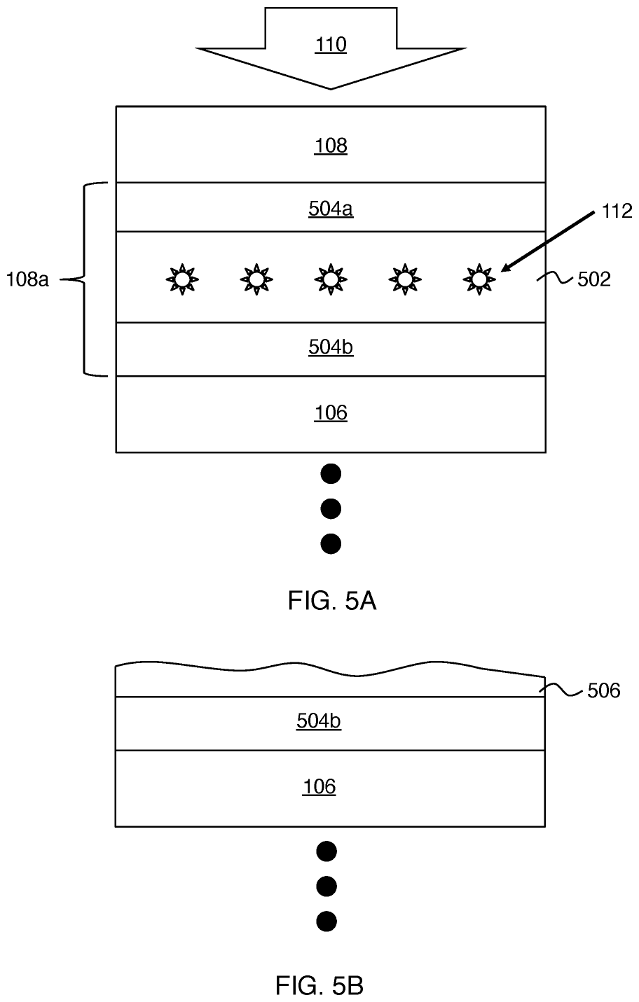

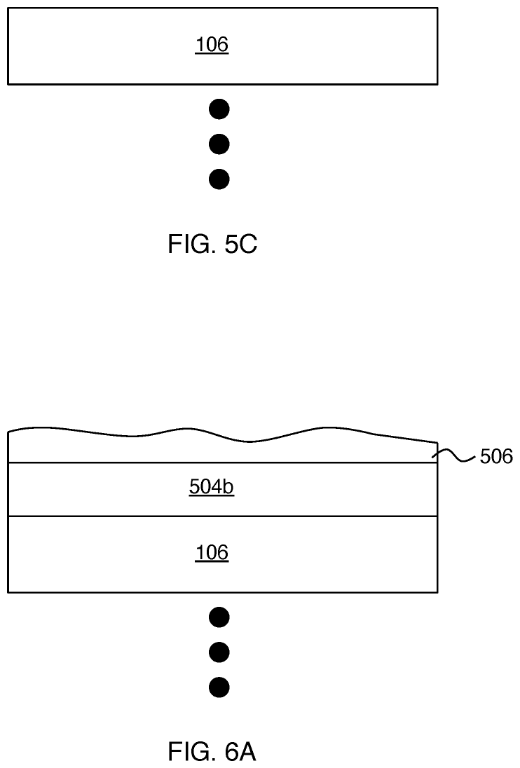

FIGS. 5A-C show a first option for a clean-up process after an ablative release. FIG. 5A shows sacrificial structure 108a including an absorber region 502 sandwiched by etch-stop regions 504a, 504b. FIG. 5A is not to scale, since sacrificial structure 108a is typically thinner than epitaxial structures 106 and 108. Here the laser radiation is all or mostly absorbed in absorber region 502. FIG. 5B shows a typical result of an ablation step, with ablation debris 506 on top of etch-stop region 504b on top of epitaxial structure 106. FIG. 5C shows the result of removing debris 506 and etch-stop region 504b in a single step to expose epitaxial structure 106. More specifically, this removal step removes exposed absorber region material and exposed etch-stop region material and does not remove exposed epitaxial structure material. Suitable removal steps include but are not limited to: wet chemical etching, dry chemical etching, chemo-mechanical polishing, electrochemical etching, or photoelectrochemical etching.

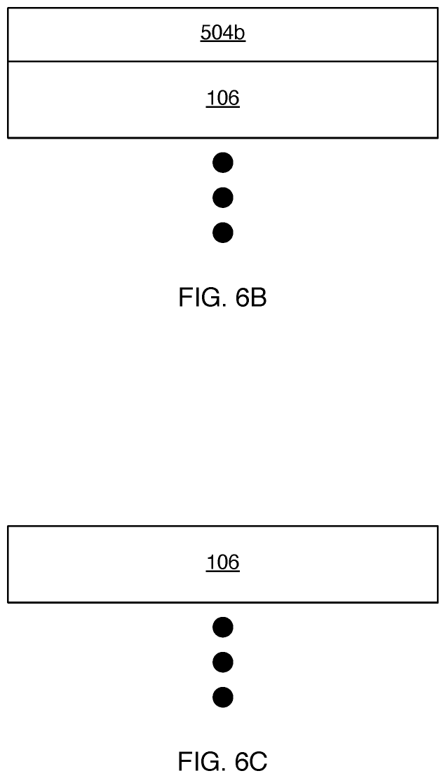

FIGS. 6A-C show a second option for a clean-up process after an ablative release. Here FIG. 6A is a repeat of FIG. 5B, showing the result after an ablation step of the structure of FIG. 5A. FIG. 6B shows the result of removing exposed absorber region debris with a first removal step that removes exposed absorber region material (and preferably stops on etch-stop region material). FIG. 6C shows the result of removing exposed etch-stop regions with a second removal step that removes exposed etch-stop region material and does not remove exposed epitaxial structure material. Thus the examples of FIGS. 5A-C and FIGS. 6A-C are single-step and two-step clean-up processes, respectively. Suitable first and second removal steps include but are not limited to: wet chemical etching, dry chemical etching, chemo-mechanical polishing, electrochemical etching, or photoelectrochemical etching.

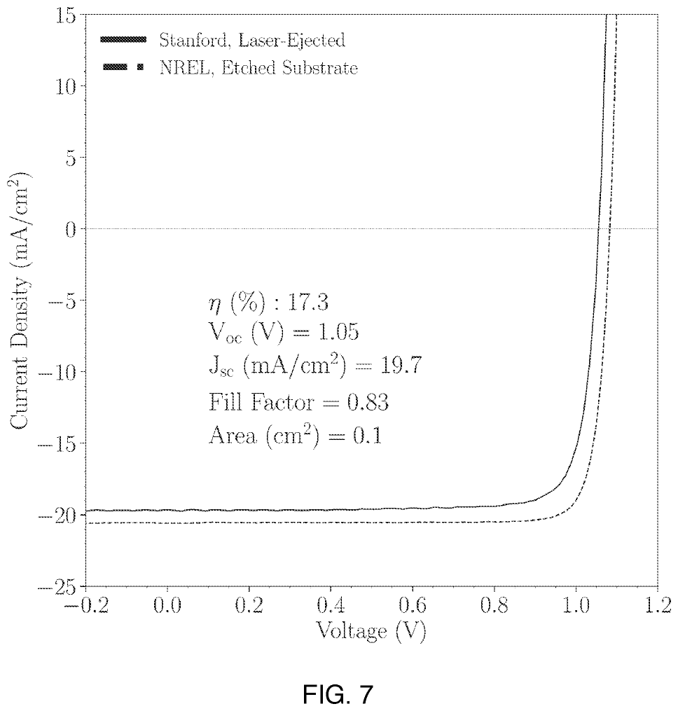

FIG. 7 shows photovoltaic testing (current density v voltage tests) of two single-junction, GaAs-based III-V solar cells, grown on and removed from a GaAs substrate. Both devices have nearly the same epitaxial structure, and both were grown with nearly identical recipes using the same epitaxy growth system at the National Renewable Energy Laboratory. The etched substrate device was created by NREL personnel, by etching away the substrate in a chemical etch. The laser-ejected cell was created by Stanford personnel, after NREL personnel shipped the as-grown epitaxial structure to Stanford, by sending a laser pulse through the GaAs substrate, which absorbed in a sacrificial release structure under the device layers, separating the epitaxial structure from the substrate. The laser-ejected cell was then finished and tested by standard procedures by Stanford personnel. The cell performance of the “laser-ejected” cell was measured at Stanford, and the “etched substrate” cell performance measured at the National Renewable Energy Laboratory (NREL). Performance metrics of the laser-ejected cell are inset in the figure.

As can be seen from FIG. 7, the laser ejected cell and the conventional cell have comparable solar cell performance, showing that laser ejection in this case did not significantly reduce material quality. We regard this single-ejection result as a partial proof of concept of multi-ejection processing as described herein.

### C) Further Considerations and Examples

The thickness of the absorber layers, absorber properties of the devices, laser pulse properties, mechanical strain conditions (intrinsic or applied), composition and doping of the layers, structural quality of the layers, thermal properties of the layers, electromagnetic effects such as Fabry-Perot resonance between layers, and other properties can change the fraction of a given laser pulse that absorbs in one or more absorber layers initially, during, or after a given laser pulse. Increasing the thickness of the top absorber layer, for example, can reduce the laser pulse transmitted into the lower light absorber layers arbitrarily to approach zero. Once the layer begins to get excited by the laser pulse, e.g. carrier excitation or heating, the layer's properties may change significantly during the time duration of the laser pulse. An absorber layer that begins as relatively transparent to the laser pulse, can become highly absorbing and reflecting during the laser pulse. With these types of strategies, one device layer can be removed at a time, or many layers can be excited in arbitrary combinations to remove more than one layer at a time from multiple absorption layers, including by sending laser pulses through the substrate side that interact with the as-grown or light-excited absorber layers, i.e. by combining this process with that described in U.S. Pat. No. 9,698,053.

The laser pulse, especially the wavelength, duration, spatial profile, and intensity (examples of “parameters”), should be kept within processing windows in order to remove high quality layers in sequence. The goal is for parameters to cause phase transformations in the sacrificial layers, especially the absorber layer, but not cause unacceptable damage in other layers, either the relevant device layer, or the device layers and sacrificial layers below the relevant device layer/sacrificial layer pair. An example goal is for the laser pulse parameters to cause a separation process below the device in a sacrificial layer, but not to cause surface damage at an incident, bonded device surface, at the sacrificial etch interface below the device, nor the sacrificial interfaces below the device.

Example 1) An example for the

AlGaAs|AlAs|GaAs|AlAs|AlGaAs|AlAs|GaAs|AlAs| (100) GaAs structure could be an 800 nm laser pulse, at 10 ns pulse duration at full width, half maximum, that is uniform in its lateral intensity profile, incident on an anti-reflection coated and glass-bonded AlAs surface, with an average fluence between 0.1 and 10 J/cm², causing separation at the top GaAs layer, but little to no effect at the lower AlGaAs|AlAs interface nor the AlAs|GaAs interface. Any of these types of processes could then be repeated with the same or different parameters, to successfully remove the next AlGaAs layer from the device.

Example 2) Another example could be an

InP|InGaAs|InP|InGaAs| (100) InP structure, using a 30 fs, 1064 nm laser pulse, with a non-uniform spatial profile, with average fluence between 1 mJ/cm² and 1 J/cm², that separates the top InP layer at the top InGaAs structure, with little or no effect at the lower InP|InGaAs| (100) InP layers.

Example 3) Another example could be a

AlGaAs|AlAs|GaAs|AlAs|AlGaAs|AlAs|GaAs|AlAs| (100) GaAs structure that is heated to 700 C with an infrared heating lamp, before sweeping a 1000 kW, 800 nm continuous wave laser across the surface, such that the GaAs layer just melts, and the combination of intrinsic and bonding-induced stress peels away the thin film from the molten GaAs layer. Any of these types of processes could then be repeated with the same or different parameters, to successfully remove all of the different layers from the device. We note that the steps do not necessarily need to be alternating between light absorption and removal of etch stops (by e.g. wet etching, dry etching, or other removal means, such as chemical-mechanical polishing).

Example 4) For example, a structure could be

AlAs|GaAs|AlAs|GaAs|AlAs|GaInP| (100) GaAs, and after light separation at the top GaAs layer, the GaAs layer could be etched to the AlAs below. After light separation at the second GaAs layer, the GaAs layer could be etched to the AlAs below, and the AlAs could be etched away with an acid or base that does not strongly etch the GaInP. Then, the GaInP|GaAs structure could be used to produce more device layers, and the process repeated. Finally, when the GaInP surface revealed by a subsequent AlAs etch became fouled, by example due to process variability, then another wet etch step could be performed which etched away the GaInP, revealing the original GaAs surface, which had previously never been exposed after the initial epitaxial cycle.

The combination of laser pulses and layers can leave the properties of any other absorber or etch layer intact for subsequent use, i.e. the separation by etching, mechanical peeling, or light, does not necessarily affect subsequent etching, mechanical peeling, or light processing steps. For example, after removal of all device layers, light liftoff layer sets, and the surrounding etch stops from the surface of a growth wafer, the next step could then remove yet another etch stop from the surface of the growth wafer, which had never been removed during any of the processing prior to its first removal. Because we do not need to remove films by mechanical peeling or chemical etching, the orthogonal ways to apply those processes are preserved until we choose to exploit them after light treatments, as applicable.

1. A method of individually separating two or more distinct epitaxial structures from a substrate, the method comprising:
i) epitaxially depositing a multilayer stack on a semiconductor substrate structure, wherein the multilayer stack includes an alternating sequence of two or more distinct epitaxial structures and two or more sacrificial structures, wherein a bottom part of the multilayer stack that is in contact with the semiconductor substrate structure is one of the sacrificial structures;
ii) illuminating the multilayer stack with one or more pulses of laser radiation such that absorption of the laser radiation in a selected one of the sacrificial structures provides ablative release from each other of structures sandwiching the selected one of the sacrificial structures; and
iii) repeating step (ii) one or more times, each repetition having a different sacrificial structure acting as the selected one of the sacrificial structures, to provide a sequence of ablative releases.

2. The method of claim 1, wherein a top part of the multilayer stack faces away from the semiconductor substrate structure, wherein the sequence of ablative releases is from top to bottom of the multilayer stack, and wherein the laser radiation is incident on the top part of the multilayer stack.

3. The method of claim 2, further comprising bonding a carrier to the top part of the multilayer stack prior to one or more of the ablative release steps, wherein the carrier is transparent to the laser radiation, whereby one or more ablatively released epitaxial structures is each disposed on its own carrier.

4. The method of claim 1, wherein a top part of the multilayer stack faces away from the semiconductor substrate structure, wherein the sequence of ablative releases is from bottom to top of the multilayer stack, and wherein the laser radiation is incident on the bottom part of the multilayer stack.

5. The method of claim 1, wherein the epitaxial structures and the sacrificial structures are lattice-matched to the semiconductor substrate structure.

6. The method of claim 1, wherein the epitaxial structures are lattice-matched to the semiconductor substrate structure and wherein the sacrificial structures are strained layers that lattice match to the semiconductor substrate structure via strain.

7. The method of claim 1, wherein the sacrificial structures each include an absorber region sandwiched by etch-stop regions, and further comprising, after each ablative release step:
removing exposed absorber region debris with a first removal step that removes exposed absorber region material; and
removing exposed etch-stop regions with a second removal step that removes exposed etch-stop region material and does not remove exposed epitaxial structure material.

8. The method of claim 7, wherein the first and second removal steps are selected from the group consisting of: wet chemical etching, dry chemical etching, chemo-mechanical polishing, electrochemical etching, and photoelectrochemical etching.

9. The method of claim 1, wherein the sacrificial structures each include an absorber region sandwiched by etch-stop regions, and further comprising, after each ablative release step:
removing exposed absorber region debris and exposed etch-stop region material with a removal step that removes exposed absorber region material and exposed etch-stop region material and does not remove exposed epitaxial structure material.

10. The method of claim 9, wherein the removal step is selected from the group consisting of: wet chemical etching, dry chemical etching, chemo-mechanical polishing, electrochemical etching, and photoelectrochemical etching.

11. The method of claim 1, further comprising:
iv) preparing the semiconductor substrate structure for re-use after performing the steps of claim 1; and
repeating the steps of claim 1.

12. The method of claim 11, wherein the semiconductor substrate structure includes two or more substrate layers forming a substrate layer stack.

13. The method of claim 1, wherein a mechanical force within the multilayer stack contributes to one or more of the ablative releases.

14. The method of claim 13, wherein the mechanical force is generated by a coefficient of thermal expansion mismatch in the multilayer stack.
